(19) United States
(12) Patent Application Publication
(10) Pub. No.: US 2026/0206131 A1
(43) Pub. Date: Jul. 16, 2026

(54) TRANSITION FROM A THIN FILM TO A THICK FILM IN ELECTRICALLY CONDUCTING DEVICES

(71) Applicant: DYCONEX AG, Bassersdorf (CH)

(72) Inventors: Roland STEIM, Dübendorf (CH); Marc Robert HAUER, Uster (CH); Zoran OSTOJIC, Bassersdorf (CH)

(73) Assignee: DYCONEX AG, Bassersdorf (CH)

(21) Appl. No.: 19/135,388

(22) PCT Filed: Nov. 13, 2023
(86) PCT No.: PCT/EP2023/081627

§ 371 Date: Jun. 4, 2025

(30) Foreign Application Priority Data
Dec. 6, 2022 (EP) 22211644.4

(51) Int. Cl. H05K 1/02; H05K 1/11; H05K 3/16

(52) U.S. Cl. CPC H05K 1/0271; H05K 1/113; H05K 3/16; H05K 2201/0338; H05K 2201/09154; H05K 2201/09509; H05K 2201/09736; H05K 2203/0346

(57) ABSTRACT

The present invention relates to a device (1) for conducting an electrical current, comprising an electrically insulating substrate (3) comprising a first side (3a), a first electrical conductor (4) arranged on the substrate (3) and comprising a first portion (40) protruding from the first side (3a) of the substrate (3), and a metallic layer (2) arranged on the first side (3a) of the substrate (3), wherein said metallic layer (2) comprises a transition region (20) overlapping at least an edge region (400) of said first portion (40) of the first electrical conductor (4). According to the invention, said edge region (400) comprises a beveled or rounded cross-sectional contour in a cross-sectional plane extending orthogonal to the first side (3a) of the substrate (3).

The present invention relates to a device for conducting an electrical current as well as to a method for producing such a device.

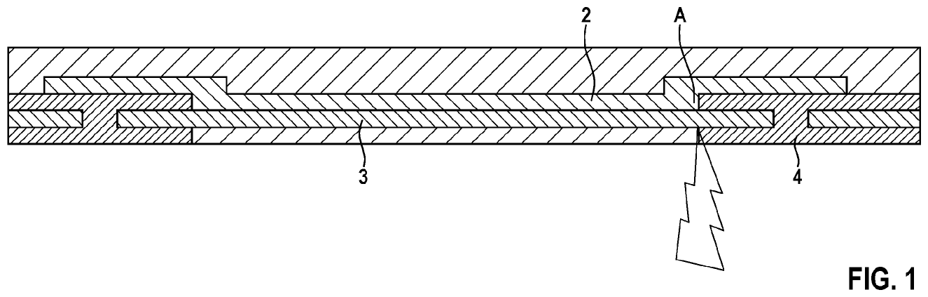

Devices of the afore-mentioned kind can comprise a thin sputtered layer 2 of the conductive pattern (cf. FIG. 1), particularly at a transition between a polyimide foil substrate 3 and a relatively thick copper conductor 4. The sputtered layer 2 (e.g., niobium, titanium, or gold) typically has a layer thickness of (0.05 μm to 1 μm) while the thick copper layer 4 rather has a layer thickness of 1 μm to 36 μm. An etched copper conductor pattern typically has a near rectangular cross section.

However, as indicated in FIG. 1, the transition A of the sputtered layer 2 from the copper 4 to the substrate 3 is susceptible to mechanical stresses such as bending and stretching. The thin film 2 can break in the area A of this bending zone. Moreover, due to the strong difference in thickness by a factor of 10 to 100, the thin film 2 sees a strong change in properties (strength, CTE, resistance, or the like) in the area A of the transition, which is unfavorable for reliable contact and easily leads to a predetermined breaking point. Moreover, when sputtering the Cu step, the vertical flank is not well/continuously covered by the sputtered film, since most of the metal is deposited on the horizontal surfaces.

Based on the above, the problem to be solved by the present invention is to provide a device for conducting an electrical current and a method for producing such a device that ensure a better transition of the thin metal film from the substrate onto the relatively thicker conductor, so that a sufficiently large contact area is obtained as well as a more reliable electrical contact. Furthermore, a higher mechanical stability of the transition shall be achieved.

This problem is solved by a device having the features of claim 1 as well as by a method having the features of claim 14. Preferred embodiments of these aspects of the present invention are stated in the corresponding dependent claims and are described below.

According to claim 1 a device for conducting an electrical current is disclosed, comprising:
an electrically insulating substrate comprising a first side,
a first electrical conductor arranged on the substrate and comprising a first portion protruding from the first side of the substrate, and
a metallic layer arranged on the first side of the substrate, wherein said metallic layer comprises a transition region overlapping at least an edge region of said first portion of the first electrical conductor.

According to the present invention, said edge region comprises a beveled or rounded cross-sectional contour in a cross-sectional plane extending orthogonal to the first side of the substrate.

In other words, the conductor thickness in the area of the transition is beveled and/or rounded. This effect can be enhanced by a finger structure/prong structure of the edge region compared to a linear edge which will be described in more detail below.

The present invention thus provides a technical solution for the transition of a thin layer (sputtered, thermally evaporated, etc.) from a substrate to thick copper (classical PCB technology). The beveling of the edge region leads to a smoother and more homogeneous transition of the thin metal film (e.g. niobium) onto the thicker film/conductor (e.g. copper). Furthermore, it ensures that there is no negative overhang in the copper conductors. Such an overhang could lead to an interruption in the sputtered layer.

This effect can be further enhanced by a serrated/finger structure. Since the resolution of the serrated structure is higher than the structure that can be etched in the conductor (e.g. copper), this leads to a flattening of the conductor (e.g. copper structure) in the transition region. In addition, this leads to a better mechanical stability because of the finger structure as a transition compared to a sharp linear edge.

The invention may be applied to electronic application or components, which usually require higher mechanical stability at junctions between different conductors as well as a reliable electrical contact between electronic components. Non-limiting examples for such components include temperature sensor, heating elements or superconductors devices. In addition to better mechanical and electrical stability in the product, this also leads to better processability-since the panel may be slightly bent or stretched here as well during manufacturing.

Accordingly in one embodiment the device according to the invention is designed as a superconductor device, a heating element, or temperature sensor, wherein particularly the metallic layer is designed or configured as a super conductor.

According to another embodiment of the present invention, the device is designed as a resistor, particularly a dump resistor, wherein first metallic layer forms the resistive conductor, and the first conductor forms a conductive track or a contact pad for electrically contacting the resistive conductor. Particularly, the first metallic layer as stated above may have various forms, e.g., a straight line, a spiral, a zig-zag line, a meander, or a plane.

According to a preferred embodiment of the device, the first electrical conductor may be at least partly designed in form of a contact pad, e.g., for making electrical connection to the device. Alternatively, or in addition, according to a preferred embodiment, the first conductor may additionally or alternatively be at least partly designed in form of a conductive track that may be used to electrically connect two electronic components to one another.

According to a preferred embodiment of the device according to the present invention, the edge region is curved in a plane extending parallel to the first side of the substrate.

Furthermore, according to a preferred embodiment of the device, the edge region forms a plurality of ramp-shaped fingers.

In a preferred embodiment, the respective finger comprises a thickness normal to the first side of the substrate, the thickness increasing towards the at least one conductor (i.e. in a direction away from a tip of the respective finger towards the remaining part of the first portion of the at least one conductor).

Furthermore, in a preferred embodiment, the respective finger comprises a width in a direction parallel to the first side of the substrate, the width increasing towards the at least one conductor (i.e. in a direction away from a tip of the respective finger towards the remaining part of the first portion of the first conductor).

According to yet another preferred embodiment, the edge region, particularly said fingers, forms a zig zag pattern.

According to yet another preferred embodiment, the edge region, particularly said fingers, comprises a meandering shape.

Furthermore, according to a preferred embodiment of the present invention, the metallic layer is a sputtered metallic layer. Preferably, the metallic layer comprises thickness in the range from 0.05 μm to 1 μm.

According to a further preferred embodiment, the metallic layer comprises or is formed out of one of: niobium, titanium, constantan, gold, nickel, chromium, a combination thereof, e.g., an alloy of nickel and chromium.

Furthermore, in a preferred embodiment, the device according to the invention further comprises a second electrical conductor arranged on a second side of the substrate, the second side facing away from the first side of the substrate, wherein the first electrical conductor and the second electrical conductor are electrically connected by a connecting portion extending through an opening in the substrate (i.e., a via).

Preferably, in an embodiment, the first electrical conductor and/or the second electrical conductor (e.g. formed as a contact pad and/or a conductive track) comprises or is formed out of copper. Preferably, the first and/or the second portion of the at least one conductor comprises a thickness in the range from 1 μm to 36 μm.

Furthermore, according to a preferred embodiment of the device according to the present invention, the substrate 3 comprises or is formed out of one of: a polyimide, a liquid crystal polymer (LCP) a fiber-reinforced polymers, e.g. an epoxy resin or polymide, BT (bismaleimide triazine)-epoxy, or an Ajionomoto Bild-up Film (ABF). Particularly, the substrate may be a foil, particularly polyimide or LCP foil.

Within the meaning of the present invention, the term “liquid crystal polymer” is used in the meaning known to and commonly used by a person skilled in the art. A “liquid crystal polymer” refers in particular to an aromatic polymer, which has highly ordered or crystalline regions in the molten state or in solution. Non-limiting examples include aromatic polyamides such as aramid (Kevlar) and aromatic polyesters of hydroxybenzoic acid, such as a polycondensate of 4-hydroxybenzoic acid and 6-hydroxynaphthalene-2-carboxylic acid (Vectran).

According to a further embodiment, a further metallic layer is arranged on said transition region of the metallic layer to further reinforce said transition region.

According to a preferred embodiment of the device, the further metallic layer is a plated metallic layer. Preferably, the further metallic layer comprises thickness in the range from 1 μm to 36 μm.

According to a further preferred embodiment of the device, the further metallic layer comprises or is formed out of copper or gold or combination thereof.

Furthermore, in a preferred embodiment, an intermediary metallic layer is arranged between the metallic layer and the further metallic layer. Preferably, the intermediary layer comprises a thickness in the range from 50 nm to 200 nm.

Furthermore, according to a preferred embodiment of the device, the intermediary metallic layer comprises one of the following metals: copper, chromium, Cr, titanium, tungsten, or combination thereof, e.g., titanium and tungsten.

Further, according to yet another preferred embodiment, the intermediary metallic layer is a sputtered metallic layer.

According to a further aspect of the present invention, a method for producing a device for conducting an electrical current, particularly a device according to the present invention, is disclosed, the method comprising the steps of:
providing an electrically insulating substrate comprising a first side, wherein a first electrical conductor is arranged on the substrate and comprises a first portion protruding from the first side of the substrate,
providing an edge region of the first portion of the at least one conductor such that said edge region comprises a beveled or rounded cross-sectional contour in a cross-sectional plane extending orthogonal to the first side of the substrate, and
sputtering a metallic layer onto the first side of the substrate, so that said metallic layer comprises a transition region overlapping at least said edge region of said first portion of the at least one conductor.

Preferably, according to an embodiment, the step of providing said edge region corresponds to etching an edge of the first portion of the first electrical conductor such that said edge region comprises a beveled and/or rounded cross-sectional contour in a cross-sectional plane extending orthogonal to the first side of the substrate.

According to a preferred embodiment of the method, a further metallic layer is provided on said transition region of the metallic layer to reinforce said transition region.

Furthermore, according to a preferred embodiment of the method, providing the further metallic layer comprises sputtering an intermediary metallic layer onto the metallic layer and plating the further metallic layer onto the intermediary layer.

Furthermore, according to a preferred embodiment of the method, a portion of said intermediary layer adjacent the further metallic layer (particularly a portion of the intermediary layer not being covered by the further metallic layer(s)) is removed by means of etching.

According to a preferred embodiment of the method, the first electrical electrically conducting conductor may be at least partly designed in form of a contact pad, e.g. for making electrical connection to the device. Alternatively, or additionally, according to a preferred embodiment, the first electrical conductor may be at least partly alternatively or additionally be designed in form of a conductive track that may be used to electrically connect two electronic components to one another.

According to yet another aspect of the present invention, a medical device, particularly an implantable medical device is disclosed, the medical device comprising a device according to the present invention.

In the following, preferred embodiments of the present invention as well as further features and advantages of the present invention are described with reference to the Figures, wherein

FIG. 1 shows a conducting structure according to the prior art having a thin sputtered metallic layer overlapping a copper conductor leading to an unfavorable predetermined breaking point at the transition of the sputtered layer from the substrate to the copper conductor,

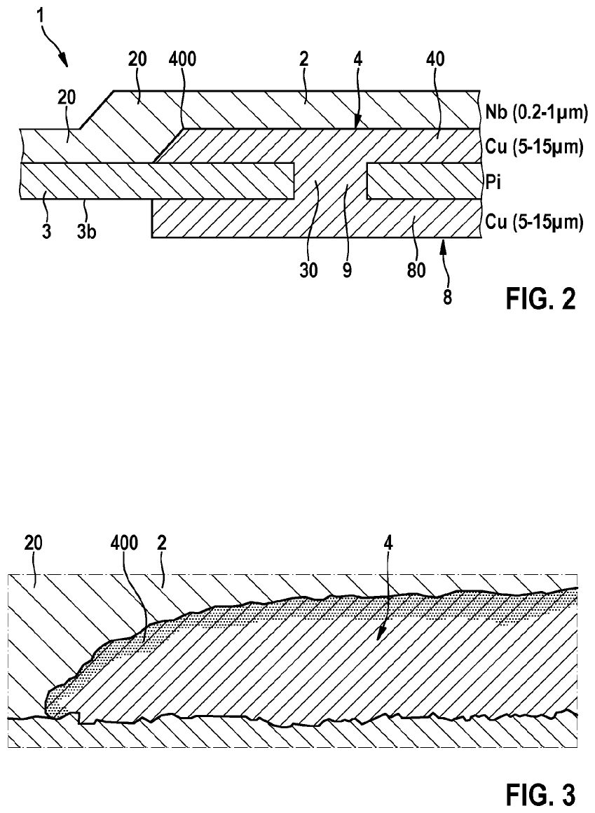

FIG. 2 shows a schematical cross-sectional view of a detail of an embodiment of the device for conducting an electrical current according to the present invention,

FIG. 3 shows a schematical cross-sectional view of a detail of a further embodiment of the device for conducting an electrical current according to the present invention. Here, the sputtered layer is too thin to be seen on the image.

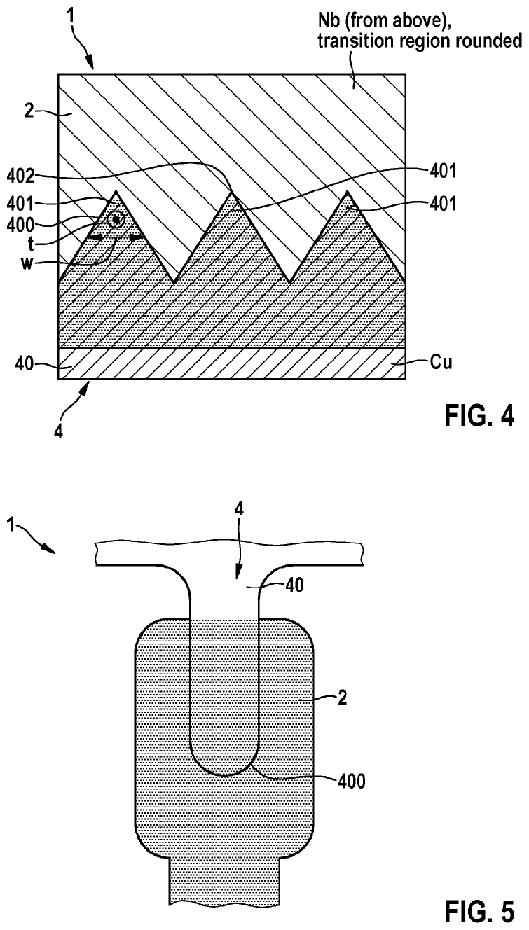

FIG. 4 shows a schematical top view onto an embodiment of the device for conducting an electrical current according to the present invention,

FIG. 5 shows a top view onto a further embodiment of the device for conducting an electrical current according to the present invention, and

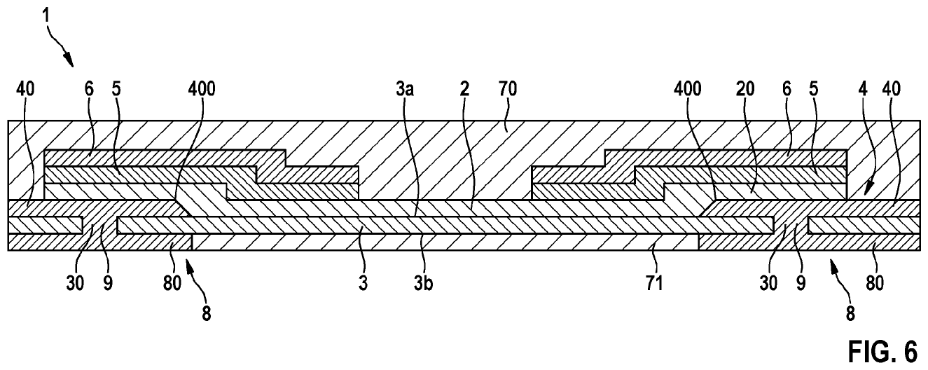

FIG. 6 shows a schematical cross-sectional view of a further embodiment of the device for conducting an electrical current according to the present invention.

FIG. 2 shows an embodiment of a device 1 according to the present invention which mitigates the disadvantages of the structure shown in FIG. 1 which comprises a pre-determined breaking point at the transition region A as described above.

Particularly, as shown in FIG. 2, the device 1 for conducting an electrical current comprises an electrically insulating substrate 3 (formed e.g. out of polyimide) comprising a first side 3a, and a first electrical conductor 4 arranged on the substrate 3 and comprising a first portion 40 protruding from the first side 3a of the substrate 3.

Further, the device 1 comprises a metallic layer 2 arranged on the first side 3a of the substrate 3, wherein said metallic layer 2 comprises a transition region 20 overlapping at least an edge region 400 of said first portion 40 of the at least one conductor 4. According to the invention, said edge region 400 comprises a beveled cross-sectional contour (as shown in FIG. 2) or a rounded cross-sectional contour (as e.g. shown in FIG. 3).

The first electrical conductor 4 may be at least partly formed a contact pad, e.g. for making an electrical connection to the device 1. The first electrical conductor 4 may alternatively or additionally at least partly be formed as a conductive track that may be used to electrically connect two electronic components to one another.

Furthermore, as shown in FIG. 2 or 6, the device according to the invention further comprises a second electrical conductor 8 preferably having a second portion 80 and being arranged on a second side 3b of the substrate 3, the second side 3b facing away from the first side 3a of the substrate 3. A connecting portion 9 (via) extends through an opening 30 in the substrate 3 and connects the first portion 40 to the fist electrical conductor 4 with the portion 80 of the second electrical conductor 9.

Particularly, the device 1 may comprise several first and second conductors 4, 8. Particularly, two first conductors 4 may be connected in an electrically conducting fashion by the metallic layer 2 (e.g. niobium). Preferably, the respective conductor 4 may be formed as a contact pad 4 or conductive track. The respective contact pad 4 or conductive track may allow electrically contacting the device 1 from the outside. Particularly, in case of the device 1 is designed as a super conductor device, the two contact pads or conductive tracks 4 may be used to contact the metallic layer 2, wherein the metallic layer 2 forms super conductor, and wherein the metallic layer is particularly formed from niobium.

According to a preferred embodiment schematically shown in FIG. 4, the edge region 400 forms a plurality of ramp-shaped fingers 401. Particularly, the respective finger 401 comprises a thickness t normal to the first side 3a of the substrate 3, the thickness t increasing towards the first electrical conductor 4 (i.e. in a direction pointing from a tip 402 of the respective finger 401 towards the remaining part of the first portion 40 of the first electrical conductor 4). Furthermore, the respective finger 401 comprises a width w in a direction parallel to the first side 3a of the substrate 3, the width w increasing towards the first electrical conductor 4.

According to yet another embodiment shown in FIG. 5, the edge region 400 is curved and may form a single finger as described above, to improve mechanical durability of the transition region 20 of the metallic layer 2 (e.g. niobium).

According to preferred embodiments, providing the beveled and/or rounded edge region 400 of the at least one conductor 4, particularly contact pad 4 or conductive track 4, may be realized in the following ways: A normal copper thinning step in the range of 1 μm to 2 μm leads to a rounded edge/ramp region 400. Particularly, an applied etching agent can attack the metal of the conductor 4 (e.g. copper) uniformly from all sides, thus corners are thinned (rounded) more than horizontal surfaces.

As already indicated above, this effect may be exploited even better by using a jagged/triangular print texture as shown in FIG. 4. Particularly, the edge region can have a meandering structure, a zig zag structure or some other serrated/jacked structure, particularly the triangular pattern shown in FIG. 4. These structures can all be considered as a plurality of fingers 401 that extend outwards from the remaining part of the first portion 40 of the respective conductor 4.

Particularly, the jagged edges at the tips 402 of the triangular fingers 401 have a resolution that exceeds that of the copper structures.

Upon etching, the rounding/thinning is greatest at the tips 402 of the fingers 401 in the thick copper 4, since here the etching agent can attack from three sides (top, left, right). The further one moves away from the tip 402, the less the thinning. At the end of the fingers 401, the opening width in the photoresist is preferably so small that an electrolyte exchange is not completely possible and the copper of the conductor 4 can only be partially etched.

Particularly, this allows a ramped finger structure to be created with a larger area of the ramp per se due to the finger structure. By avoiding a linear transition, the occurrence of a predetermined breaking point is prevented.

Furthermore, as shown in FIG. 6, the transition region 20 of the sputtered metallic layer 2 (e.g. niobium) can be further reinforced, by providing a further metallic layer 6 on said transition region 20 of the metallic layer 2, which transition region 20 extends from the substrate 3 over the conductor 4. This provides an additional reinforcement of the transition region 20 and prevents damages of the metallic (e.g. sputtered) layer 2.

Particularly, the metallic layer 2 may be a conductive pattern of Nb (niobium) that may be applied to the substrate 3 and the conductor 4 by way of sputtering. In addition, a thin intermediary layer 5 (e.g. a copper layer that preferably has a thickness in the range from 50 nm to 1000 nm) can be sputtered directly onto the metallic layer 2, wherein the further metallic layer 6 (e.g. Cu) is (galvanically) plated on top of the intermediary layer 5. Excess portions of the intermediary layer 5 not being covered by a further metallic layer 6 can be removed by way of etching, to again expose the metallic layer 2 (e.g. niobium).

Furthermore, the metallic layer 2 (e.g. niobium) and/or the further metallic layer(s) 6 can be covered by an insulating layer 70. Likewise, the second side 3b of the substrate 3 can be covered by an insulating layer 71 as well, with the portion(s) 80 of the second conductor(s) 8 being at least partially exposed, so that the respective conductor 8 (e.g. contact pad) can be electrically contacted (e.g. by soldering a conductor to it). The respective insulating layer 70, 71 can be formed out of a liquid crystal polymer (LCP) or a polyimide.

Also, the other embodiments shown in FIGS. 1 to 5 may comprise such insulating layers 70, 71 covering the metallic layer 2 and the second side 3b of the substrate 3.

Assemblies of thick copper (etched classical PCB structures) in combination with thin films (other metals such as niobium) are interesting for numerous applications. Here, the transition 20 from the thin film 2 onto the thick film 4 is always critical and a weak point. The invention offers a safe solution here. Particularly, via technology and the contacts pads or conductive tracks 4 for contacting may be made in the classic thick film copper technology.

A beveling/rounding of the copper stage 4 allows a smooth transition of the metallic layer 2 (e.g. niobium) over a ramp onto the thick copper 4. Here, there is no homogeneity/continuity problem of the niobium since the transition is particularly oblique and not vertical.

Combining a finger structure as described herein with a bevel/rounding of the copper step 4 allows a mechanically and electrically more stable transition which avoids a longer sharp critical bending zone.

1. A device (1) for conducting an electrical current, comprising
an electrically insulating substrate (3) comprising a first side (3a),
a first conductor (4) arranged on the substrate (3) and comprising a first portion (40) protruding from the first side (3a) of the substrate (3), and
a metallic layer (2) arranged on the first side (3a) of the substrate (3), wherein said metallic layer (2) comprises a transition region (20) overlapping at least an edge region (400) of said first portion (40) of the first electrical conductor (4),
characterized in that
said edge region (400) comprises a beveled or rounded cross-sectional contour in a cross-sectional plane extending orthogonal to the first side (3a) of the substrate (3).

2. The device according to claim 1, wherein the edge region (400) is curved in a plane extending parallel to the first side (3a) of the substrate (3).

3. The device according to claim 1, wherein the edge region (400) forms a plurality of ramp-shaped fingers (401).

4. The device according to claim 3, wherein the respective finger (401) comprises a thickness (t) normal to the first side (3a) of the substrate (3), the thickness (t) increasing towards the first electrical conductor (4).

5. The device according to claim 3, wherein the respective finger (401) comprises a width (w) in a direction parallel to the first side (3a) of the substrate (3), the width (w) increasing towards the first electrical conductor (4).

6. The device according to claim 1, wherein the edge region (400) forms a zig zag pattern.

7. The device according to claim 1, wherein the edge region (400) comprises a meandering shape.

8. The device according to claim 1, wherein the metallic layer (2) is a sputtered metallic layer.

9. The device according to claim 1, wherein the metallic layer (2) comprises or is formed out of one of: niobium, titanium, constantan, gold, nickel, chromium, or combination thereof.

10. The device according to claim 1, further comprising a second electrical conductor (8) arranged on a second side (3b) of the substrate (3), the second side (3b) facing away from the first side (3a) of the substrate (3), wherein the first electrical conductor (4) and the second electrical conductor (8) are electrically connected by a connecting portion (41) extending through an opening (30) in the substrate (3).

11. The device according to claim 1, wherein the substrate (3) comprises or is formed out of one of: a polyimide, a liquid crystal polymer, a fiber-reinforced polymer or an Ajionomoto Bild-up Film.

12. The device according to claim 1, wherein a further metallic layer (6) is arranged on said transition region (20) of the metallic layer (2) to reinforce said transition region (20).

13. The device according to claim 12, wherein an intermediary metallic layer (5) is arranged between the metallic layer (2) and the further metallic layer (6).

14. A method for producing a device for conducting an electrical current, the method comprising the steps of:
providing an electrically insulating substrate (3) comprising a first side (3a), wherein a first electrical conductor (4) is arranged on the substrate (3) and comprises a first portion (40) protruding from the first side (3a) of the substrate (3),
providing an edge region (400) of the first portion (40) of the first electrical conductor (4) such that said edge region (400) comprises a beveled or rounded cross-sectional contour in a cross-sectional plane extending orthogonal to the first side (3a) of the substrate (3), and
sputtering a metallic layer (2) onto the first side (3a) of the substrate (3), so that said metallic layer (2) comprises a transition region (20) overlapping at least said edge region (400) of said first portion (40) of the at least one conductor (4).

15. The method according to claim 14, wherein the step of providing said edge region (400) corresponds to etching an edge of the first portion (40) of the first electrical conductor (4) such that said edge region (400) comprises a beveled and/or rounded cross-sectional contour in a cross-sectional plane extending orthogonal to the first side (3a) of the substrate (3).
